(19) United States
(12) Patent Application Publication
(10) Pub. No.: US 2016/0052019 A1
(43) Pub. Date: Feb. 25, 2016

(54) PIEZOELECTRIC DEVICE AND ELECTRONIC DEVICE INCLUDING THE SAME

(71) Applicant: INNOCHIPS TECHNOLOGY CO., LTD., Ansan-Si (KR)

(72) Inventors: In Kil PARK, Seongnam-Si (KR); Tae Hyung NOH, Siheung-Si (KR); Sung Cheol PARK, Ansan-Si (KR); Young Sul KIM, Seoul (KR); Kyung Seob YOON, Suwon-Si (KR); Hee Seob SHIN, Siheung-Si (KR); In Seob JUNG, Ansan-Si (KR)

(21) Appl. No.: 14/710,574

(22) Filed: May 12, 2015

(30) Foreign Application Priority Data
Aug. 19, 2014 (KR) 10-2014-0107856

(51) Int. Cl. B06B 1/06; H01L 41/09

(52) U.S. Cl. CPC B06B 1/06; H01L 41/09

(57) ABSTRACT

Provided is a piezoelectric device including a first piezoelectric plate, and at least one second piezoelectric plate configured to contact at least one area of the first piezoelectric plate, wherein the first and second piezoelectric plates have different resonant frequencies.

### CROSS-REFERENCE TO RELATED APPLICATION

This application claims priority to Korean Patent Application No. 2014-0107856 filed on Aug. 19, 2015 and all the benefits accruing therefrom under 35 U.S.C. §119, the contents of which are incorporated by reference in their entirety.

### BACKGROUND

The present disclosure relates to a piezoelectric device, and more particularly, to a piezoelectric device usable as a piezoelectric acoustic device and piezoelectric vibration device and an electronic device including the same.

A wireless call function itself such as voice or message transmission and reception is a main purpose in a typical mobile terminal. However, as recently a smart phone is developed, the wireless call function is merely a simple function and performances of various functions such as internet, applications, TV, navigation, and SNS become the main purpose.

Accordingly, in order to conveniently use various functions of a smart phone, a display unit of a smart phone is enlarged, the size thereof gets large, and technology rapidly developed including internet speed, operation, or pupil recognition allows a user to more conveniently use a smart phone terminal with. In addition, in the market, a smart phone terminal to which various functions are added is rapidly released with fierce competition between companies.

However, as the display is enlarged and accordingly the size of the smart phone terminal gets larger in order to realize various functions of a smart phone, when wearing casual dress for taking a walk or exercising, it is inconvenient to carry or a robbery or loss case may occur. In addition, when possessing the smart phone in a bag, it is inconvenient to take the smart phone out of the bag for an incoming or outgoing call, or using a messaging function. There is also a limitation in that vibration or a ring tone of the smart phone in the bag is not heard by a user to allow the user not to receive an incoming call or message.

In order to solve the limitation, a technique enabling to be mounted on a human body, namely wearable technique is being developed. As a typical example, Korean Patent Application Laid-open Publication Nos. 10-2009-0046306 and 10-2012-0083804 respectively disclose “A band type mobile terminal” and “Mobile terminal modifiable to bracelet type”. In addition, Korean Patent Application Laid-open Publication No. 10-2013-0054309 also discloses “Human body-mounted auxiliary mobile device assembly”. Such typical techniques enable the wearable device, namely, an auxiliary mobile device to be carried in a watch, or necklace type.

### SUMMARY

The present disclosure provides a piezoelectric device usable as at least any one of a piezoelectric sound device and piezoelectric vibration device.

The present disclosure also provides a piezoelectric device capable of generating a sound and vibration by being mounted in an electronic device and operated as at least any one of the piezoelectric sound device and piezoelectric vibration device according to an applied signal.

The present disclosure also provides an electronic device including a piezoelectric device usable as at least any one of the piezoelectric sound device and piezoelectric vibration device mounted therein to reduce an area occupied by the piezoelectric device.

In accordance with another exemplary embodiment, a piezoelectric device includes a first piezoelectric plate; and at least one second piezoelectric plate configured to contact at least one area of the first piezoelectric plate, wherein the first and second piezoelectric plates have different resonant frequencies.

The first and second piezoelectric plates may have different shapes.

The first piezoelectric plate may be provided in a frame shape of which a central part is vacant.

The second piezoelectric plate may contact at least one area of the first piezoelectric plate to be provided in an inner area of the first piezoelectric plate.

The second piezoelectric plate may include a protrusion part at a predetermined area and the protrusion part contacts at least one area of the first piezoelectric plate.

The piezoelectric device may further include a dummy plate provided at a predetermined area of the first piezoelectric plate, wherein the second piezoelectric plate is connected to the dummy plate.

The piezoelectric device of claim may further include a load provided in at least one area of the first and second piezoelectric plates.

The piezoelectric device may further include a vibration plate disposed between the first and second piezoelectric plates.

In accordance with yet another exemplary embodiment, an electric device includes: a piezoelectric device configured to include a first piezoelectric plate and at least one second piezoelectric plate configured to contact at least one area of the first piezoelectric plate, the first and second piezoelectric plates having different resonant frequencies, wherein the piezoelectric device operates as at least one of a piezoelectric sound device and a piezoelectric vibration device according to a signal applied to the first and second piezoelectric plates.

The electronic device may be separated from a main body of a mobile terminal to perform an auxiliary function of the mobile terminal, and be wearable.

The first and second piezoelectric plates may include different shapes.

The first piezoelectric plate may be provided in a predetermined frame shape and the second piezoelectric plate is formed from at least one area of the first piezoelectric plate to an inner area of the first piezoelectric plate.

The electronic device may further include a load provided at least one area of the first and second piezoelectric plates.

The electronic device may further include a vibration plate disposed between the first and second piezoelectric plates.

### BRIEF DESCRIPTION OF THE DRAWINGS

Exemplary embodiments can be understood in more detail from the following description taken in conjunction with the accompanying drawings, in which:

FIG. 1 is an exploded perspective view of a piezoelectric device according to an exemplary embodiment;

FIGS. 2 to 4 are exploded perspective views of piezoelectric devices according to other exemplary embodiments;

FIGS. 5A to 8D are plan views of piezoelectric devices according to various modification examples of an embodiment;

FIGS. 9 and 10 are graphs representing sound pressure characteristics of a typical piezoelectric device and a piezoelectric device according to an exemplary embodiment; and

FIG. 11 is a graph representing vibration characteristic of a piezoelectric device according to an exemplary embodiment.

### DETAILED DESCRIPTION OF EMBODIMENTS

Hereinafter, specific embodiments will be described in detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art.

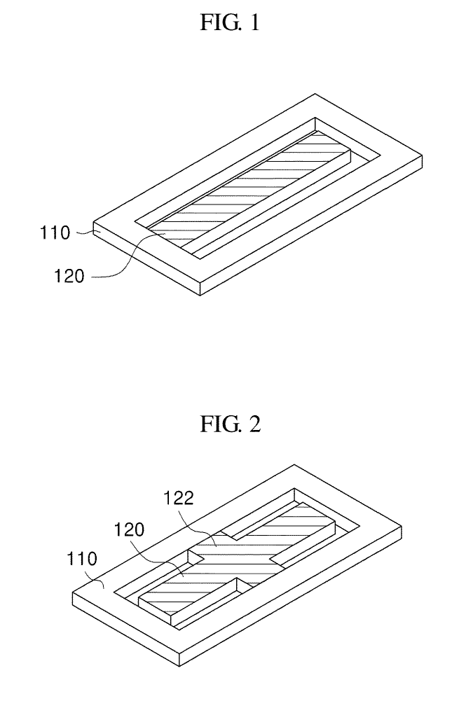

FIG. 1 is an exploded perspective view of a piezoelectric device in accordance with an exemplary embodiment.

Referring to FIG. 1, a piezoelectric device according to an embodiment may include a first piezoelectric plate 110, and a second piezoelectric plate 120 disposed to contact at least one area of the first piezoelectric plate 110. Here, the first and second piezoelectric plates 110 and 120 may be disposed in different shapes and have different resonant frequencies.

The first piezoelectric plate 110 is provided to have an approximately rectangular frame shape having a predetermined width and vacant inner part. The first piezoelectric plate 110 may be provided in various shapes such as a square, circle, ellipse, and polygon as well as the rectangular frame shape. The first piezoelectric plate 110 may include a substrate and a piezoelectric layer in which the substrate is formed on at least one surface. For example, the first piezoelectric plate 110 may be formed in a bimorph type in which piezoelectric layers are formed on both sides of a substrate, or in a unimorph type in which a piezoelectric layer is formed on one side of a substrate. The piezoelectric layer may be formed by stacking at least one layer, or a plurality of layers. In addition, electrodes may be respectively formed on the top and bottom portions of the piezoelectric layer. In other words, a plurality of piezoelectric layers and a plurality of electrodes may be alternately stacked to realize the first piezoelectric plate 100. Here, the piezoelectric layer may be formed of a piezoelectric material, for example, PZT (Pb, Zr, Ti), NKN (Na, K, Nb), or BNT (Bi, Na, Ti)-based material. In addition, the piezoelectric layer may be polarized in different directions or an identical direction and stacked. In other words, when a plurality of piezoelectric layers are formed on one surface of a substrate, polarizations of each of the plurality of piezoelectric layers may be alternately formed in different directions or in an identical direction. Furthermore, the substrate may use a material, for example, a metal or plastics, having a characteristic that vibration may be generated while a structure in which the piezoelectric layers are stacked may be maintained. However, the first piezoelectric plate 100 may not employ a substrate of a different material from that of the piezoelectric layer. In other words, in the first piezoelectric plate 100, an unpolarized piezoelectric layer may be provided at the central portion and a plurality of piezoelectric layers polarized in different directions may be stacked at the top and bottom portions thereof. Furthermore, an electrode pattern (not illustrated) to which a driving signal is applied may be formed on at least one area of the first piezoelectric plate 100. For example, the electrode pattern may be provided on edges of the top or bottom surface of the first piezoelectric plate 110. At least two electrode patterns may be formed separately from each other and connected to an electronic device, for example, an auxiliary mobile device through connection to connection terminals (not illustrated). The first piezoelectric plate 100 may be driven as a piezoelectric sound device or a piezoelectric vibration device according to a signal applied through an electronic device, namely, AC power.

The second piezoelectric plate 120 is manufactured in a different shape from the first piezoelectric plate 110 to contact at least one area of the first piezoelectric plate 110. At this point, the first and second piezoelectric plates 110 and 120 may be directly contacted. For example, the second piezoelectric plate 120 is provided to have a bar shape having a predetermined width and length and to contact one area of the first piezoelectric plate 110 in a space in the first piezoelectric plate 110 of a frame shape. In other words, the first piezoelectric plate 110 may be provided in an approximately rectangular frame shape having two opposite long sides and two opposite short sides, and the second piezoelectric plate 120 may be provided to contact at least one area of the first piezoelectric plate 110 to be inside the first piezoelectric plate 110. Here, the thickness of the second piezoelectric plate 120 may be identical to or different from that of the first piezoelectric plate 110. In addition, the second piezoelectric plate 120 may be formed in an identical process to the first piezoelectric plate 110 and manufactured with a predetermined area removed therefrom, or formed in a different process and then bonded to be manufactured. In other words, a piezoelectric device may be implemented by removing an area between the first and second piezoelectric plates 110 and 120 from an approximately rectangular plate and accordingly the thicknesses of the first and second piezoelectric plates 110 and 120 may be identical. Accordingly, the first and second piezoelectric plates 110 and 120 may directly contact to be formed without an adhesive provided therebetween. In addition, the first piezoelectric plate 110 in a frame shape is formed and then the second piezoelectric plate 120 formed in a bar shape is bonded to at least one area on the first piezoelectric plate 110 so that a piezoelectric device in which the second piezoelectric plate 120 is provided in the first piezoelectric plate 110 may be manufactured. Accordingly, the first and second piezoelectric plates 110 and 120 may be bonded with an adhesive provided therebetween. Furthermore, an area of a space between the first and second piezoelectric plates 110 and 120 and an area of the second piezoelectric plate 120 may have a ratio of 5:1 to 1:5. A resonant frequency of a piezoelectric device may be controlled by adjusting a ratio of an area in a space between the first and second piezoelectric plates 110 and 120 and an area of the second piezoelectric plate 120. The second piezoelectric plate 120 may include a substrate and a piezoelectric layer in which the substrate is formed at least one surface. In other words, the second piezoelectric plate 120 may be provided in an identical stack structure to that of the first piezoelectric plate 110. For example, the second piezoelectric plate 120 may be formed in a bimorph type in which piezoelectric layers are formed on both sides of the substrate, or in a unimorph type in which a piezoelectric layer is formed on one side of the substrate. The piezoelectric layer may be formed by stacking at least one layer, or a plurality of layers. In addition, electrodes may be respectively formed on the top and bottom portions of the piezoelectric layer. In other words, a plurality of piezoelectric layers and a plurality of electrodes may be stacked to realize the second piezoelectric plate 120. In addition, the piezoelectric layer may be polarized in different directions or an identical direction to be stacked. In other words, when a plurality of piezoelectric layers are formed on one surface of a substrate, polarizations of each of the plurality of piezoelectric layers may be alternately formed in different directions or in an identical direction. Furthermore, the substrate may use a material having a characteristic that vibration may be generated while a structure in which the piezoelectric layers are stacked may be maintained, for example, a metal or plastics. However, the second piezoelectric plate 120 may not employ a substrate of a different material from that of the piezoelectric layer. In other words, the second piezoelectric plate 120 may provide an unpolarized piezoelectric layer at the central portion and a plurality of piezoelectric layers polarized in different directions may be stacked at the top and bottom portions thereof. Furthermore, an electrode pattern (not illustrated) to which a driving signal is applied may be formed on a predetermined area of the second piezoelectric plate 120, for example, an area overlapping the first piezoelectric plate 110. At least two electrode patterns may be formed separately from each other and connected to an electronic device, for example, an auxiliary mobile device through connection to connection terminals (not illustrated). The second piezoelectric plate 120 may be driven as a piezoelectric sound device or a piezoelectric vibration device according to a signal applied through an electronic device, namely, an AC power.

As described above, a piezoelectric device according to an embodiment may include a first piezoelectric plate 110, and a second piezoelectric plate 120 contacting at least one area of the first piezoelectric plate 110 and provided in a space in the first piezoelectric plate 110. In other words, in a piezoelectric device of an embodiment, at least two piezoelectric plates 110 and 120 may be provided to have at least one contact point. At this point, the at least two piezoelectric plate 110 and 120 may have different shapes and different resonant frequencies. Such a piezoelectric device may be separated from an electronic device, for example, a smart phone to be provided in an auxiliary mobile device performing an auxiliary function of the smart phone, namely, a wearable device mountable on a body and may operate as at least any one of a piezoelectric speaker and a piezoelectric actuator according to a signal provided from the electronic device. In other words, the piezoelectric device may operate as a piezoelectric sound device or a piezoelectric vibration device, or may simultaneously operate as the piezoelectric sound device and piezoelectric vibration device. Accordingly, an embodiment is a complex device in which the first and second piezoelectric plates 100 and 300 having different shapes and resonant frequencies are provided with a vibration plate 200 disposed therebetween, and which is applied to an electronic device such as an auxiliary mobile device to generate sound and vibration.

FIGS. 2 to 4 are exploded perspective views of piezoelectric devices according other exemplary embodiments.

Referring to FIG. 2, a piezoelectric device according to another embodiment may include a first piezoelectric plate 110 having an approximately rectangular frame shape, and a second piezoelectric plate 120 contacting two areas of the first piezoelectric plate 110 and provided in a space in the first piezoelectric plate 110. In other words, the second piezoelectric plate 120 is provided in the inner space of the first piezoelectric plate 110 and has protrusion parts 122 of two areas, which are formed from the central portions of long sides of the second piezoelectric plate 120 to contact the long sides of the first piezoelectric plates 110. Compared to the embodiment of FIG. 1, while one short side of the second piezoelectric plate 120 contacts the first piezoelectric plate 110 in the embodiment of FIG. 1, two long side areas of the second piezoelectric plate 120 contact the first piezoelectric plate 110 in the other embodiment of FIG. 2.

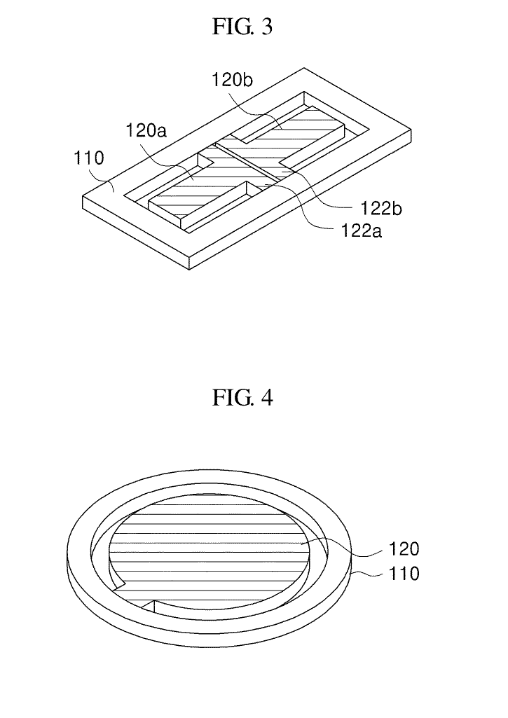

Referring to FIG. 3, a piezoelectric device according to still another embodiment may include a first piezoelectric plate 110 having an approximately rectangular frame shape, and a 2a and 2b piezoelectric plates 120a and 120b contacting one area of the first piezoelectric plate 110 and provided in a space in the first piezoelectric plate 110. In other words, the 2a and 2b piezoelectric plates 120a and 120b are separated from each other at the central portions of the long sides of the first piezoelectric plate 110, and two protrusion parts 122a and 122b are formed from predetermined areas of the 2a and 2b piezoelectric plates 120a and 120b, for example, areas corresponding to the central portions of the long sides of the first piezoelectric plate to contact the first piezoelectric plate 110. Compared to the other embodiment of FIG. 2, in still another embodiment of FIG. 3, the central portion of the area contacting the first piezoelectric plate 110 is cut to form the 2a and 2b piezoelectric plates 120a and 120b.

Referring to FIG. 4, a piezoelectric device according to still another embodiment may include a first piezoelectric plate 110 having an approximately rectangular frame shape, and a second piezoelectric plate 120 contacting one area of the first piezoelectric plate 110 and provided in a space in the first piezoelectric plate 110. In other words, the piezoelectric device of an embodiment may be provided in a circular shape. In addition, the second piezoelectric plate 120 is provided in a circular shape, and one area of the second piezoelectric plate 120 is extended to contact a predetermined area of the first piezoelectric plate 110. The first and second piezoelectric plates 110 and 120 may also have different shapes. For example, the first piezoelectric plate 110 may be provided in a circular shape, and the second piezoelectric plate 120 may be provided in a quadrangular shape.

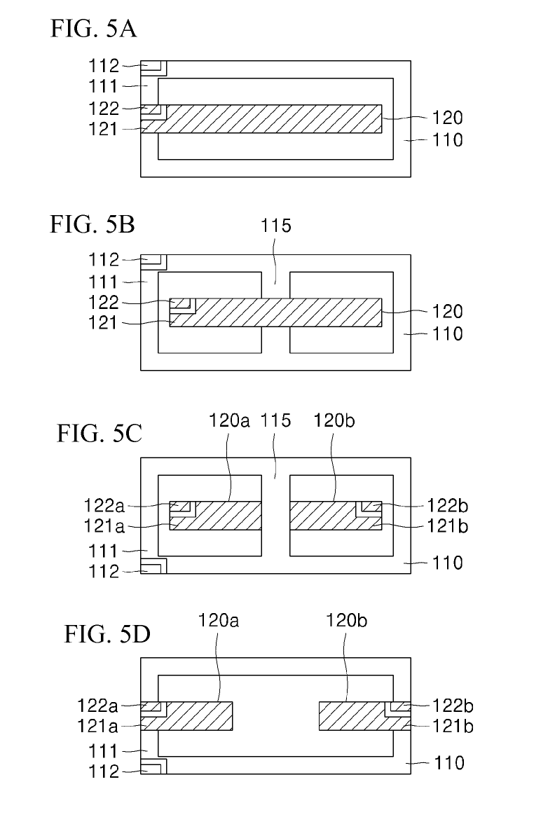

Furthermore, a piezoelectric device of an embodiment may be diversely changed in a shape and accordingly various frequency characteristics can be obtained. FIG. 5 illustrates a piezoelectric device according to various modification examples of an embodiment.

As illustrated in FIG. 5A, a piezoelectric device includes a first piezoelectric plate 110 having an approximately rectangular frame shape, and a second piezoelectric plate 120 contacting one short side of the first piezoelectric plate 110 to be provided in a space of the first piezoelectric plate 110 in a long side direction of the first piezoelectric plate 110. In addition, at least two electrode patterns 111 and 112 are formed on the top surface of the first piezoelectric plate 110 and at least two electrode patterns 121 and 122 are formed on the top surface of the second piezoelectric plate 120. AC power having different polarities may be applied to the electrode patterns 111 and 112 of the first piezoelectric plate 110 and AC power having different polarities may also be applied to the electrode patterns 121 and 122 of the second piezoelectric plate 120.

As illustrated in FIG. 5B, a piezoelectric device includes a first piezoelectric plate having an approximately rectangular frame shape, a dummy plate 115 provided between predetermined areas of two opposite long sides of the first piezoelectric plate 110, and a second piezoelectric plate 120 making contact on the dummy plate 115 and provided in a long side direction of the first piezoelectric plate 110. The dummy plate 115 may be formed to have a predetermined width between, for example, central portions of two opposite long sides. In addition, the dummy plate 115 may be formed in an identical stack structure to that of the first piezoelectric plate 110 to vibrate according to an applied voltage. However, the dummy plate 115 may be not polarized and may not vibrate. Here, the dummy plate 115 may be formed to have an identical width to, or be wider or narrower than the width of the first piezoelectric plate 110. In addition, the central portion of the second piezoelectric plate 120 may make contact on the dummy plate 115. In other words, the second piezoelectric plate 120 may allow the central portion thereof to make contact on the dummy plate 115 and be provided in an area in the first piezoelectric plate 110 in a long side direction of the first piezoelectric plate 110. In addition, at least two electrode patterns 111 and 112 are formed on the top surface of the first piezoelectric plate 110 and at least two electrode patterns 121 and 122 are formed on the top surface of the second piezoelectric plate 120 to have AC power having different polarities applied thereto.

As illustrated in FIG. 5C, a piezoelectric device may include a first piezoelectric plate 110 having an approximately rectangular frame shape, a dummy plate 115 provided between predetermined areas, for example, the central portions, of two opposite long sides of the first piezoelectric plate 110, and 2a and 2b piezoelectric plates 120a and 120b provided in opposite directions from the dummy plates 115. In other words, the 2a and 2b piezoelectric plates 120a and 320b may separately contact two side surfaces or the top surface of the dummy plate 115 to be formed in a long side direction of the first piezoelectric plate 110. In addition, at least two electrode patterns 121a and 122a may be formed on the top surface of the second piezoelectric plate 120a and at least two electrode patterns 121b and 122b may also be formed on the top surface of a third piezoelectric plate 120b. AC power having different polarities may be applied to each of the electrode patterns. In addition, at least two electrode patterns 111 and 112 may be formed on the top surface of the first piezoelectric plate 110 and AC power having different polarities may be applied thereto.

As illustrated in FIG. 5D, a piezoelectric device may include a first piezoelectric plate 110 having an approximately rectangular frame shape, and 2a and 2b piezoelectric plates 120a and 120b extended along a long side direction of the first piezoelectric plate 110 from two opposite short sides of the first piezoelectric plate 110. In other words, the 2a and 2b piezoelectric plates 120a and 120b are formed in a long side direction of the first piezoelectric plate 110 from the top surface or side surfaces of two opposite short sides of the first piezoelectric plate 110 and provided to be separated by a predetermined interval at the central area in the first piezoelectric plate 110. Here, at least two electrode patterns 121a and 122a may be formed on the top surface of the 2a piezoelectric plate 120a and at least two electrode patterns 121b and 122b may also be formed on the top surface of the 2b piezoelectric plate 120b. AC power having different polarities may be applied to each of the electrode patterns. In addition, at least two electrode patterns 111 and 112 may be formed on the top surface of the first piezoelectric plate 110 and AC power having different polarities may be applied thereto.

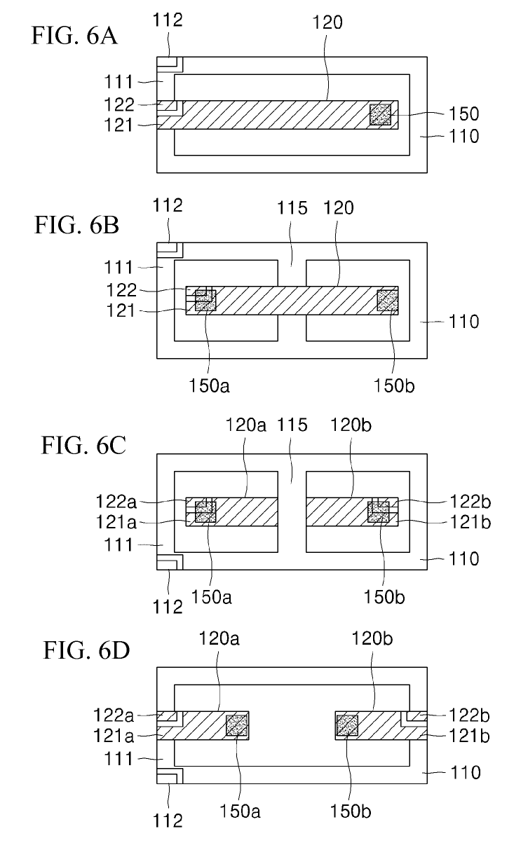

In addition, a piezoelectric device of an embodiment has a load provided on at least one area to increase a vibration force and accordingly frequency characteristic may be diversely changed. Weight, position, and form of the load may be diversely modified and accordingly various vibration forces may be realized. FIG. 6 illustrates a piezoelectric device according to various modification examples of an embodiment.

As illustrated in FIG. 6A, a piezoelectric device may include a first piezoelectric plate 110 having an approximately rectangular frame shape and a second piezoelectric plate 120 contacting a predetermined area of one short side of the first piezoelectric plate 110 to be provided in a long side direction of the first piezoelectric plate 110, and a load 150 may be provided on one end portion of the first piezoelectric plate 120, which does not contact the first piezoelectric plate 110.

As illustrated in FIG. 6B, a piezoelectric device includes a first piezoelectric plate 110 having an approximately rectangular frame shape and having a dummy plate 115 formed between one long side and the other long side opposite to each other, a second piezoelectric plate 120 making contact on the dummy plate 115 and provided in a long side direction of the first piezoelectric plate 110, and loads 150a and 150b respectively provided on two opposite end portions of the second piezoelectric plate 120. In other words, the load 150a may be provided on electrode patterns 121 and 122 of the second piezoelectric plate 120, to which AC power is applied.

As illustrated in FIG. 6C, a piezoelectric plate includes a first piezoelectric plate 110 having an approximately rectangular frame shape and having a dummy plate 115 formed between one long side and the other long side opposite to each other, 2a and 2b piezoelectric plates 120a and 120b contacting two sides of the dummy plate 115 and provided in a long side direction of the first piezoelectric plate 110, and loads 150a and 150b respectively formed on two opposite end portions of the 2a and 2b piezoelectric plates 120a and 120b, which do not contact the dummy plate 115. In addition, at least two electrode patterns 121a and 122a may be formed on the top surface of the 2a piezoelectric plate 120a and at least two electrode patterns 121b and 122b may also be formed on the top surface of the 2b piezoelectric plate 120b. In other words, the loads 150a and 150b may be provided on the electrode patterns 121a, 122a, 121b, and 122b of the 2a and 2b piezoelectric plates 120a and 120b, to which AC power is applied. In addition, at least two electrode patterns 111 and 112 may be formed on the top surface of the first piezoelectric plate 110 and AC power having different polarities may be applied thereto.

As illustrated in FIG. 6D, a piezoelectric device includes a first piezoelectric plate 110 having an approximately rectangular frame shape, 2a and 2b piezoelectric plates 120a and 120b formed in a long side direction of the first piezoelectric plate 110 from two opposite short sides of the first piezoelectric plate 110 to be separated by a predetermined interval at the central area in the first piezoelectric plate 110, and loads 150a and 150b formed on the end portions of the 2a and 2b piezoelectric plates 120a and 120b. In addition, at least two electrode patterns 121a and 122a may be formed on the top surface of the 2a piezoelectric plate 120a and at least two electrode patterns 121b and 122b may also be formed on the top surface of the 2b piezoelectric plate 120b. In other words, the loads 150a and 150b may be provided on areas of the 2a and 2b 120a and 120b, to which AC power is not applied. In addition, at least two electrode patterns 111 and 112 may be formed on the top surface of the first piezoelectric plate 110 and AC power having different polarities may be applied thereto.

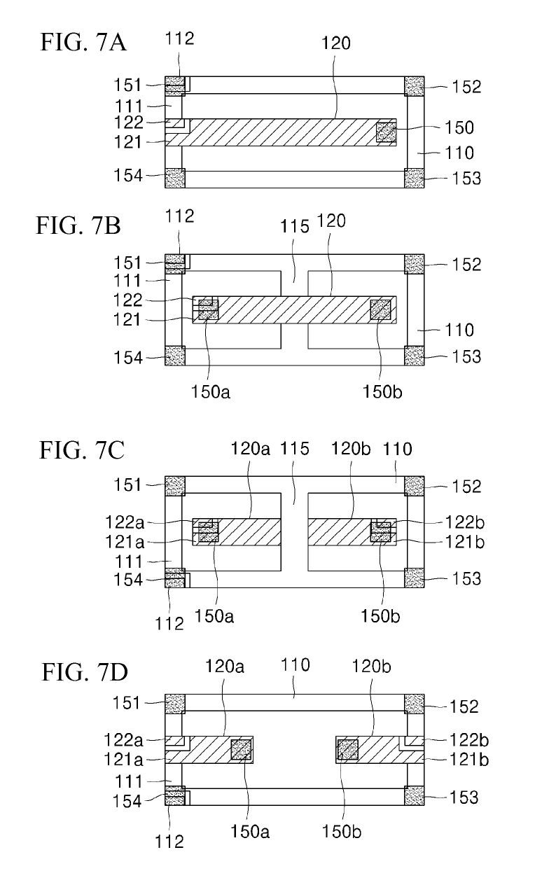

In addition, the loads may be formed on a predetermined area of the first piezoelectric plate 110 as well as the second piezoelectric plate 120, and FIGS. 7A to 7D illustrate piezoelectric devices on which loads are formed on the first and second piezoelectric plates 110 and 120.

As illustrated in FIG. 7A, a piezoelectric device may include a first piezoelectric plate 110 having an approximately rectangular frame shape and a second piezoelectric plate 120 provided at a predetermined area of one short side of the first piezoelectric plate 110 in a long side direction of the first piezoelectric plate 110 in a space in the first piezoelectric plate 110, and a load 150 may be provided on one end portion of the second piezoelectric plate 120, which does not contact the first piezoelectric plate 110. A plurality of loads 151, 152, 153, and 154 may be provided on corner areas of the first piezoelectric plate 110.

As illustrated in FIG. 7B, a piezoelectric device includes a first piezoelectric plate 110 having an approximately rectangular frame shape and having a dummy plate 115 formed between one long side and the other long side opposite to each other, a second piezoelectric plate 120 making contact on the dummy plate 115 and provided in a long side direction of the first piezoelectric plate 110, loads 150a and 150b respectively provided on two opposite end portions of the second piezoelectric plate 120, and a plurality of loads 151, 152, 153, and 154 provided on corner areas of the first piezoelectric plate 110.

As illustrated in FIG. 7C, a piezoelectric device includes a first piezoelectric plate 110 having an approximately rectangular frame shape and having a dummy plate 115 formed between one long side and the other long side opposite to each other, 2a and 2b piezoelectric plates 120a and 120b contacting two side surfaces of the dummy plate 115 and provided on an area in the first piezoelectric plate 110 in a long side direction of the first piezoelectric plate 110, loads 150a and 150b respectively provided on the 2a and 2b piezoelectric plates 120a and 120b, and a plurality of loads 151, 152, 153, and 154 provided on corner areas of the first piezoelectric plate 110.

As illustrated in FIG. 7D, a piezoelectric device includes a first piezoelectric plate 110 having an approximately rectangular frame shape, 2a and 2b piezoelectric plates 120a and 120b formed in a long side direction of the first piezoelectric plate 110 from two opposite short sides of the first piezoelectric plate 110 and separated by a predetermined interval at the central area in the first piezoelectric plate 110, loads 150a and 150b formed on the end portions of the 2a and 2b piezoelectric plates 120a and 120b, and a plurality of loads 151, 152, 153, and 154 provided on corner areas of the first piezoelectric plate 110.

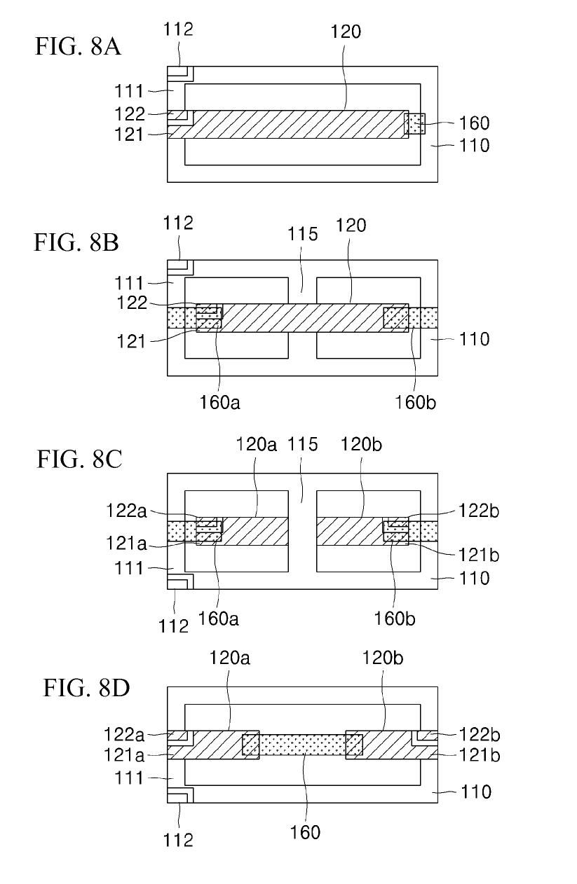

Furthermore, a piezoelectric device of an embodiment may provide a vibration plate on at least one area to increase a vibration force and accordingly frequency characteristic may be diversely changed. The vibration plate may use a material such as a polymer, a metal, or silicon, the size thereof may be diversified, and accordingly the vibration force may be diversely realized. FIGS. 8A to 8D illustrate piezoelectric devices according to various modification examples of an embodiment.

As illustrated in FIG. 8A, a piezoelectric device may include a first piezoelectric plate 110 having an approximately rectangular frame shape and a second piezoelectric plate 120 provided at a predetermined area of one short side of the first piezoelectric plate 110 in a long side direction of the first piezoelectric plate 110 in the first piezoelectric plate 110, and a vibration plate 160 may be provided between one end portion of the second piezoelectric plate 120, which does not contact the first piezoelectric plate 110, and a short side of the first piezoelectric plate 110.

As illustrated in FIG. 8B, a piezoelectric device includes a first piezoelectric plate 110 having an approximately rectangular frame shape and having a dummy plate 115 formed between one long side and the other long side opposite to each other, a second piezoelectric plate 120 making contact on the dummy plate 115 and provided in a long side direction of the first piezoelectric plate 110 on an area in the first piezoelectric plate 110, and vibration plates 160a and 160b provided between two end portions of the second piezoelectric plate 120, and the first piezoelectric plate 110. In other words, the vibration plates 160a and 160b may be provided to connect each end portion of the second piezoelectric plate 120 and the first piezoelectric plate 110.

As illustrated in FIG. 8C, a piezoelectric device includes a first piezoelectric plate 110 having an approximately rectangular frame shape and having a dummy plate 115 formed between one long side and the other long side opposite to each other, 2a and 2b piezoelectric plates 120a and 120b contacting two side surfaces of the dummy plate 115 and provided in a long side direction of the first piezoelectric plate 110 on an area in the first piezoelectric plate 110, and vibration plates 160a and 160b respectively provided between end portions of the 2a and 2b piezoelectric plates 120a and 120b and the first piezoelectric plate 110.

As illustrated in FIG. 8D, a piezoelectric device includes a first piezoelectric plate 110 having an approximately rectangular frame shape, 2a and 2b piezoelectric plates 120a and 120b formed in a long side direction of the first piezoelectric plate 110 from two opposite short sides of the first piezoelectric plate 110 and separated by a predetermined interval at the central area in the first piezoelectric plate 110, and a vibration plate 160 provided between end portions of the 2a and 2b piezoelectric plates 120a and 120b. In other words, the vibration plate 169 may be provided to connect each of the end portions of the 2a and 2b piezoelectric plate 120a and 120b, which do not contact the first piezoelectric plate 110.

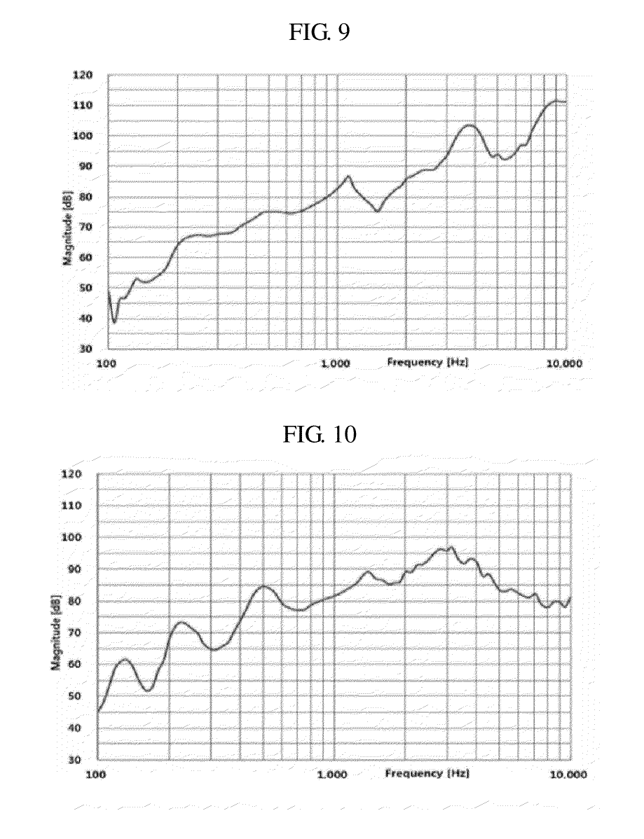

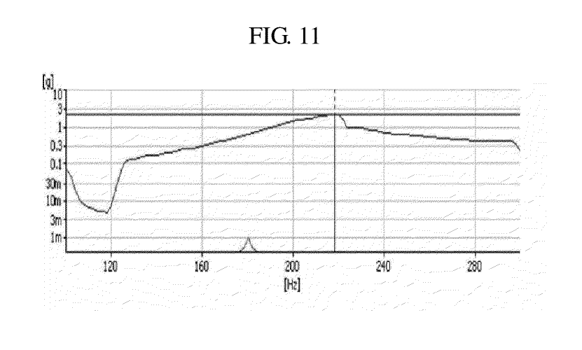

FIG. 9 is a graph representing sound pressure characteristic of a typical piezoelectric device and FIG. 10 is a graph representing sound pressure characteristic of a piezoelectric device according to an embodiment. In other words, the typical piezoelectric device has an approximately rectangular plate shape having the predetermined thickness in a shape that an inner part of the first piezoelectric plate of the embodiment is filled, and the piezoelectric device of the embodiment has a shape in which the first and second piezoelectric plates are coupled. The typical piezoelectric device has a resonant frequency of approximately 1.12 kHz and sound pressure characteristic of approximately 82 dB as represented in FIG. 9. However, the piezoelectric device according to the embodiment in which the first and second piezoelectric plates are coupled has a resonant frequency of approximately 150 kHz and sound pressure characteristic of approximately 60 dB as represented in FIG. 10 In addition, the piezoelectric device of the embodiment also has resonant frequencies of approximately 210 Hz and 500 Hz. Accordingly, at least two resonant frequencies may be generated and a resonant frequency of several hundred Hz that is lower than that of the typical one can be obtained. Accordingly, the piezoelectric device of an embodiment may be used as a sound device in an electronic device such as an auxiliary mobile device. In addition, FIG. 11 is a graph representing vibration characteristic of a piezoelectric device according to an embodiment, which exhibits an approximately 2.2G output at a resonant frequency of approximately 228 Hz. Accordingly, the piezoelectric device according to the embodiment may be used as a vibration device in an electronic device such as an auxiliary mobile device. Consequently, the piezoelectric device of the embodiment may be selectively used as a sound device and vibration device in an electronic device such as an auxiliary mobile device.

A piezoelectric device according to embodiments includes at least two piezoelectric plates having different resonant frequencies. The piezoelectric device according to embodiments is disposed in an electronic device such as an auxiliary mobile device to operate as at least any one of the piezoelectric sound device and piezoelectric vibration device according to a signal provided from the electronic device. Accordingly, an area occupied in the auxiliary mobile device can be reduced and accordingly the size and weight of the auxiliary mobile device can also be reduced by applying the piezoelectric device according to embodiments to the auxiliary mobile device, etc., in comparison to a typical technique that a sound device and vibration device are separately applied. In addition, a piezoelectric device according to embodiments can modify a structure or shape of a contact point, or apply a load or vibration plate to adjust a resonant frequency.

Although a piezoelectric device and an electronic device including the same have been described with reference to the specific embodiments, they are not limited thereto. Therefore, it will be readily understood by those skilled in the art that various modifications and changes can be made thereto without departing from the spirit and scope of the present invention defined by the appended claims.

What is claimed is:

1. A piezoelectric device comprising:
a first piezoelectric plate; and
at least one second piezoelectric plate configured to contact at least one area of the first piezoelectric plate,
wherein the first and second piezoelectric plates comprise different resonant frequencies.

2. The piezoelectric device of claim 1, wherein the first and second piezoelectric plates comprise different shapes.

3. The piezoelectric device of claim 2, wherein the first piezoelectric plate is provided in a frame shape of which a central part is vacant.

4. The piezoelectric device of claim 3, wherein the second piezoelectric plate contacts at least one area of the first piezoelectric plate to be provided in an inner area of the first piezoelectric plate.

5. The piezoelectric device of claim 4, wherein the second piezoelectric plate comprises a protrusion part at a predetermined area and the protrusion part contacts at least one area of the first piezoelectric plate.

6. The piezoelectric device of claim 4, further comprising a dummy plate provided at a predetermined area of the first piezoelectric plate,
wherein the second piezoelectric plate is connected to the dummy plate.

7. The piezoelectric device of claim 4, further comprising a vibration plate disposed between the first and second piezoelectric plates.

8. The piezoelectric device of claim 4, further comprising a load provided in at least one area of the first and second piezoelectric plates.

9. The piezoelectric device of claim 8, further comprising a vibration plate disposed between the first and second piezoelectric plates.

10. An electric device comprising:
a piezoelectric device configured to comprise a first piezoelectric plate and at least one second piezoelectric plate configured to contact at least one area of the first piezoelectric plate, the first and second piezoelectric plates having different resonant frequencies,
wherein the piezoelectric device operates as at least one of a piezoelectric sound device and a piezoelectric vibration device according to a signal applied to the first and second piezoelectric plates.

11. The electronic device of claim 10, wherein the electronic device is separated from a main body of a mobile terminal to perform an auxiliary function of the mobile terminal, and is wearable.

12. The electronic device of claim 11, wherein the first and second piezoelectric plates comprise different shapes.

13. The electronic device of claim 12, wherein the first piezoelectric plate is provided in a predetermined frame shape and the second piezoelectric plate is formed from at least one area of the first piezoelectric plate to an inner area of the first piezoelectric plate.

14. The electronic device of claim 13, further comprising a vibration plate disposed between the first and second piezoelectric plates.

15. The electronic device of claim 13, further comprising a load provided at least one area of the first and second piezoelectric plates.

16. The electronic device of claim 15, further comprising a vibration plate disposed between the first and second piezoelectric plates.
